(19) United States
(12) Patent Application Publication
(10) Pub. No.: US 2025/0344582 A1
(43) Pub. Date: Nov. 6, 2025

(54) DISPLAY DEVICE AND METHOD FOR MANUFACTURING SAME

(71) Applicant: SHARP DISPLAY TECHNOLOGY CORPORATION, Kameyama City, Mie (JP)

(72) Inventors: Makoto TSUJI, Kameyama City, Mie (JP); Takushi MIHOTANI, Kameyama City, Mie (JP); Tadashi NISHIOKA, Kameyama City, Mie (JP)

(21) Appl. No.: 18/864,195

(22) PCT Filed: Jul. 5, 2022
(86) PCT No.: PCT/JP2022/026709

§ 371 Date: Nov. 8, 2024

(51) Int. Cl. H10K 59/126; H05K 9/00; H10K 59/12

(52) U.S. Cl. CPC H10K 59/126; H05K 9/0084; H10K 59/1201

(57) ABSTRACT

A display device includes: a display panel; and a film substrate which is mounted at an edge portion of the display panel and on which an integrated circuit chip is mounted. The display device includes, on the film substrate, a chip protection layer and an electromagnetic shielding layer layered on the chip protection layer integrally provided to cover the integrated circuit chip and a peripheral portion of the integrated circuit chip. A thickness of the chip protection layer is greater than a thickness of the integrated circuit chip, and the chip protection layer is formed of a curable resin, and includes a cured portion of the curable resin provided to surround the integrated circuit chip or cover the integrated circuit chip in a plan view, and an uncured portion of the curable resin provided in a part other than the cured portion.

### TECHNICAL FIELD

The disclosure relates to a display device and a method for manufacturing the same.

### BACKGROUND ART

In recent years, as a display device replacing a liquid crystal display device, a self-luminous organic electroluminescence (hereinafter also referred to as “EL”) display device using an organic EL element attracts attention.

For example, PTL 1 discloses a method for manufacturing an organic EL device in which a driving semiconductor chip is mounted on a terminal portion of an organic EL panel, the mounted driving semiconductor chip is thinned in dry etching, and the organic EL panel having the thinned driving semiconductor chip is sandwiched and sealed between two protective films.

### CITATION LIST

### Patent Literature

PTL 1: JP 2011-40268 A

### SUMMARY

### Technical Problem

Incidentally, in most cases of a display device such as an organic EL display device or a liquid crystal display device, for example, a chip-on-film (COF) is mounted at an edge portion of the display panel to drive the display panel. Here, the COF is formed by mounting an integrated circuit (IC) chip on a flexible printed circuit (FPC). In addition, because the COF preferably includes, for example, an IC protective tape attached in a U shape to surround the IC chip to physically protect the IC chip, and a metal tape attached on the IC protective tape to electromagnetically protect the IC chip, in such a case, a protective tape attachment step of attaching an IC protective tape onto the COF and a metal tape attachment step of attaching a metal tape need to be performed after the COF is mounted at the edge portion of the display panel. However, since the IC protective tape and the metal tape need to be attached after aligning each of the tapes in the protective tape attachment step and the metal tape attachment step, there is room for improvement.

The disclosure has been made in view of such circumstances, and an object thereof is to ensure easy physical and electromagnetic protection of an IC chip on an FPC.

### Solution to Problem

In order to achieve the above object, a display device according to the disclosure includes a display panel, and a film substrate which is mounted at an edge portion of the display panel and on which an integrated circuit chip is mounted, the display device including, on the film substrate, a chip protection layer and an electromagnetic shielding layer layered on the chip protection layer integrally provided to cover the integrated circuit chip and a peripheral portion of the integrated circuit chip, in which a thickness of the chip protection layer is greater than a thickness of the integrated circuit chip, and the chip protection layer is formed of a curable resin, and includes a cured portion of the curable resin provided to surround the integrated circuit chip or cover the integrated circuit chip in a plan view, and an uncured portion of the curable resin provided in a part other than the cured portion.

In addition, a method for manufacturing a display device according to the disclosure includes a mounting step of mounting a film substrate on which an integrated circuit chip is mounted at an edge portion of a display panel, an attachment step of attaching, on the film substrate, a covering material formed by layering a chip protection layer and an electromagnetic shielding layer from a chip protection layer side to cover the integrated circuit chip and a peripheral portion of the integrated circuit chip on the film substrate, the chip protection layer being formed by applying a curable resin on a back surface of a radio wave shielding sheet and formed of the curable resin thicker than the integrated circuit chip, and the electromagnetic shielding layer being formed of the radio wave shielding sheet, and a curing step of partially curing the chip protection layer, in which, in the curing step, a cured portion is formed by curing the chip protection layer to surround the integrated circuit chip or to cover the integrated circuit chip in a plan view and an uncured portion is formed in a part other than the cured portion.

### Advantageous Effects of Disclosure

According to the disclosure, an IC chip on an FPC can be physically and electromagnetically protected with ease.

### BRIEF DESCRIPTION OF DRAWINGS

FIG. 1 is a perspective view of an organic EL display device according to a first embodiment of the disclosure.

FIG. 2 is a plan view of a display region of an organic EL display panel constituting the organic EL display device according to the first embodiment of the disclosure.

FIG. 3 is a cross-sectional view of the display region of the organic EL display panel constituting the organic EL display device according to the first embodiment of the disclosure.

FIG. 4 is an equivalent circuit diagram of a thin film transistor layer constituting the organic EL display panel of the organic EL display device according to the first embodiment of the disclosure.

FIG. 5 is a cross-sectional view of an organic EL layer constituting the organic EL display panel of the organic EL display device according to the first embodiment of the disclosure.

FIG. 6 is a perspective view illustrating an attachment step in a method for manufacturing an organic EL display device according to the first embodiment of the disclosure.

FIG. 7 is a perspective view illustrating a curing step in the method for manufacturing an organic EL display device according to the first embodiment of the disclosure.

FIG. 8 is a perspective view illustrating a curing step in a method for manufacturing an organic EL display device according to a second embodiment of the disclosure.

FIG. 9 is a perspective view of an organic EL display device according to a third embodiment of the disclosure.

FIG. 10 is a perspective view illustrating a curing step in a method for manufacturing an organic EL display device according to the third embodiment of the disclosure.

FIG. 11 is a perspective view of an organic EL display device according to a fourth embodiment of the disclosure.

FIG. 12 is a perspective view illustrating a curing step in a method for manufacturing an organic EL display device according to the fourth embodiment of the disclosure.

FIG. 13 is a perspective view illustrating a curing step in a method for manufacturing an organic EL display device according to a fifth embodiment of the disclosure.

### DESCRIPTION OF EMBODIMENTS

Embodiments of the disclosure will be described below in detail with reference to the drawings. Further, the disclosure is not limited to each of the embodiments to be described below.

### First Embodiment

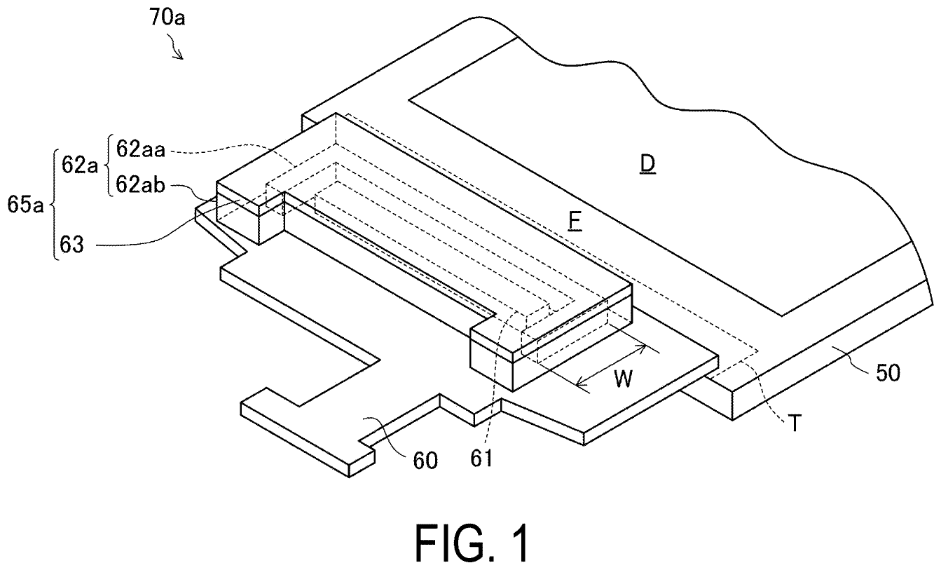

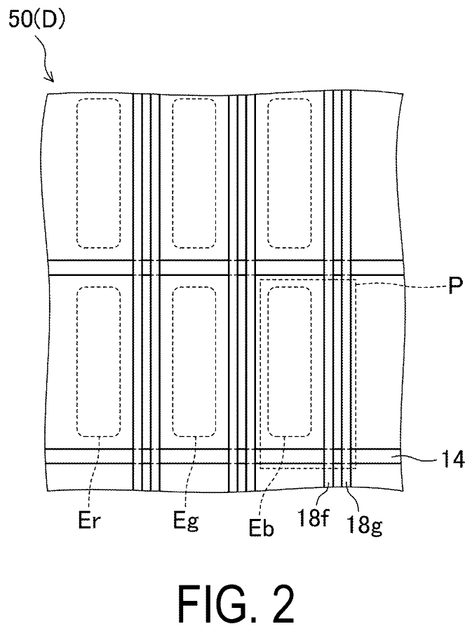

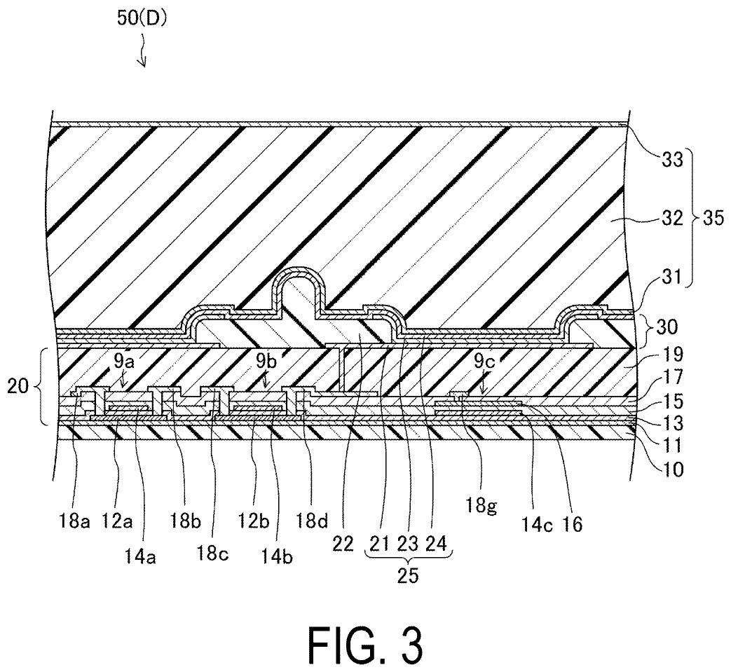

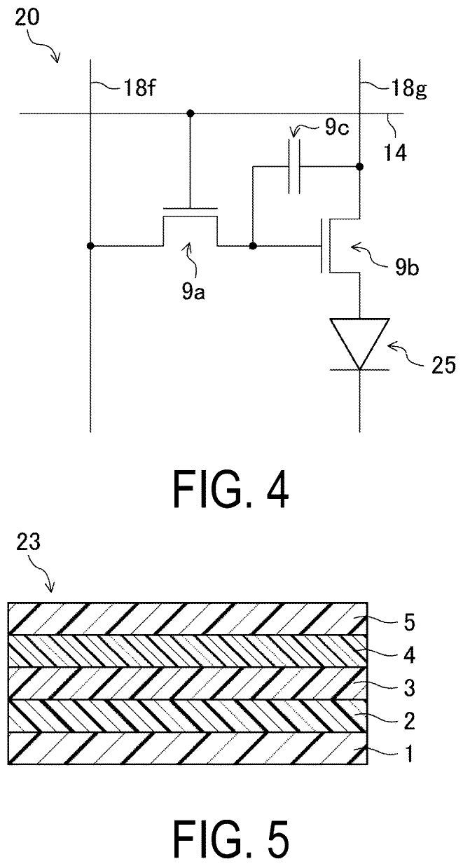

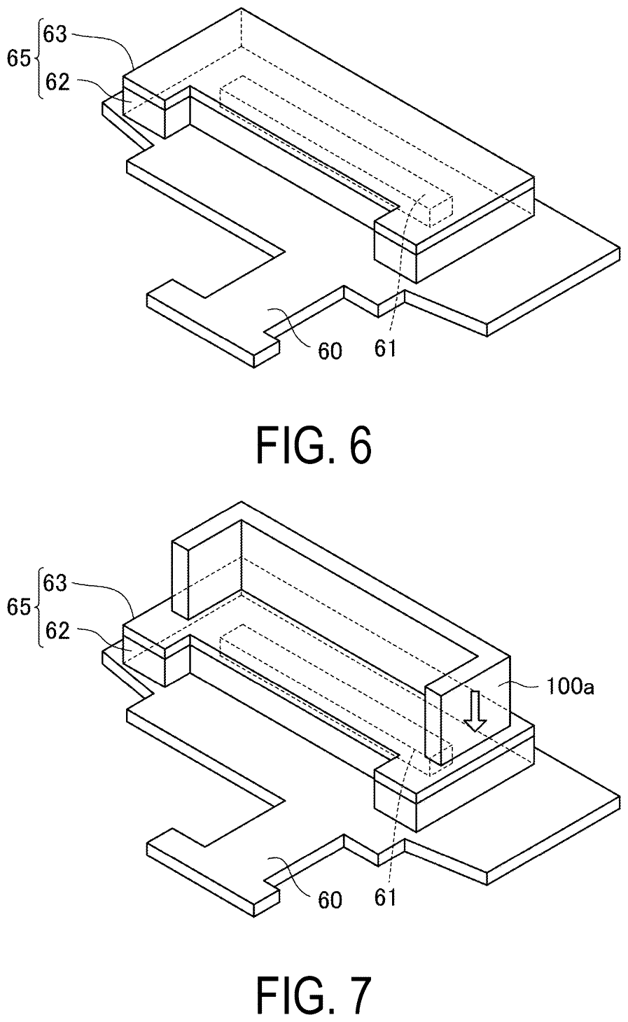

FIG. 1 to FIG. 7 illustrate a first embodiment of a display device and a method for manufacturing the display device according to the disclosure. Further, in each of the following embodiments, an organic EL display device including an organic EL display panel will be exemplified as a display device including a display panel. Here, FIG. 1 is a perspective view of an organic EL display device 70a according to the present embodiment. In addition, FIG. 2 is a plan view of a display region D of an organic EL display panel 50 constituting the organic EL display device 70a. In addition, FIG. 3 is a cross-sectional view of the display region D of the organic EL display panel 50. In addition, FIG. 4 is an equivalent circuit diagram of a thin film transistor layer 20 constituting the organic EL display panel 50. In addition, FIG. 5 is a cross-sectional view of an organic EL layer 23 constituting the organic EL display panel 50. In addition, FIG. 6 is a perspective view illustrating an attachment step in a method for manufacturing the organic EL display device 70a. In addition, FIG. 7 is a perspective view illustrating a curing step in the method for manufacturing the organic EL display device 70a.

As illustrated in FIG. 1, the organic EL display device 70a includes, for example, the organic EL display panel 50 provided in a rectangular plate shape and a FPC 60 provided as a film substrate mounted on an edge portion of the organic EL display panel 50.

As illustrated in FIG. 1, the organic EL display panel 50 includes, for example, the display region D that is provided in a rectangular shape and in which an image is displayed, and a frame region F provided in a frame shape surrounding the display region D. Further, although the display region D having the rectangular shape is exemplified in the present embodiment, the rectangular shape includes a substantial rectangular shape such as a shape whose sides are arc-shaped, a shape whose corners are arc-shaped, and a shape in which a part of a side has a notch.

As illustrated in FIG. 2, a plurality of subpixels P are arrayed in a matrix shape in the display region D. In addition, in the display region D, for example, a subpixel P including a red light-emitting region Er configured to display in a red color, a subpixel P including a green light-emitting region Eg configured to display in a green color, and a subpixel P including a blue light-emitting region Eb configured to display in a blue color are provided adjacent to one another, as illustrated in FIG. 2. Further, one pixel is configured by, for example, the three adjacent subpixels P including the red light-emitting region Er, the green light-emitting region Eg, and the blue light-emitting region Eb in the display region D. In addition, a terminal portion T is provided at the edge portion on the left front side of the frame region F in FIG. 1. Further, the FPC 60 is mounted on the terminal portion T via an anisotropic conductive film (ACF), for example, as illustrated in FIG. 1.

As illustrated in FIG. 3, the organic EL display panel 50 includes a resin substrate 10, the thin film transistor (hereinafter, also referred to as a “TFT”) layer 20 provided on the resin substrate 10, an organic EL element layer 30 provided on the TFT layer 20, and a sealing film 35 provided on the organic EL element layer 30.

The resin substrate 10 is formed of, for example, a polyimide resin.

As illustrated in FIG. 3, the TFT layer 20 includes a base coat film 11 provided on the resin substrate 10, a plurality of first TFTs 9a, a plurality of second TFTs 9b, and a plurality of capacitors 9c, which are provided on the base coat film 11, and a flattening film 19 provided on each first TFT 9a, each second TFT 9b, and each capacitor 9c. Here, as illustrated in FIGS. 2 and 4, a plurality of gate lines 14 are provided in the TFT layer 20 to extend parallel to each other in the horizontal direction in the drawings. In addition, as illustrated in FIGS. 2 and 4, a plurality of source lines 18f are provided on the TFT layer 20 to extend parallel to each other in the vertical direction in the drawings. In addition, as illustrated in FIGS. 2 and 4, a plurality of power source lines 18g are provided on the TFT layer 20 to extend parallel to each other in the vertical direction in the drawings. Further, the power source lines 18g are provided adjacent to the source lines 18f, respectively, as illustrated in FIG. 2.

The base coat film 11, and a gate insulating film 13, a first interlayer insulating film 15, and a second interlayer insulating film 17 to be described below are composed of, for example, a single-layer film or a layered film of an inorganic insulating film of silicon nitride, silicon oxide, silicon oxynitride, or the like.

The first TFT 9a is electrically connected to the corresponding gate line 14 and source line 18f in each of the subpixels P, as illustrated in FIG. 4. In addition, the first TFT 9a includes a semiconductor layer 12a, the gate insulating film 13, a gate electrode 14a, the first interlayer insulating film 15, the second interlayer insulating film 17, and a source electrode 18a and a drain electrode 18b provided in order on the base coat film 11 as illustrated in FIG. 3. Here, the semiconductor layer 12a is provided in an island shape on the base coat film 11 as illustrated in FIG. 3, and has, for example, a channel region, a source region, and a drain region. In addition, the gate insulating film 13 is provided to cover the semiconductor layer 12a as illustrated in FIG. 3. In addition, the gate electrode 14a is provided on the gate insulating film 13 to overlap the channel region of the semiconductor layer 12a as illustrated in FIG. 3. In addition, the first interlayer insulating film 15 and the second interlayer insulating film 17 are provided to cover the gate electrode 14a in order as illustrated in FIG. 3. In addition, the source electrode 18a and the drain electrode 18b are provided separate from each other on the second interlayer insulating film 17 as illustrated in FIG. 3. In addition, the source electrode 18a and the drain electrode 18b are electrically connected to the source region and the drain region of the semiconductor layer 12a, respectively, via contact holes formed in the layered film of the gate insulating film 13, the first interlayer insulating film 15, and the second interlayer insulating film 17 as illustrated in FIG. 3.

The second TFT 9b is electrically connected to the corresponding first TFT 9a and power source line 18g in each of the subpixels P as illustrated in FIG. 4. In addition, the first TFT 9b includes a semiconductor layer 12b, the gate insulating film 13, a gate electrode 14b, the first interlayer insulating film 15, the second interlayer insulating film 17, and a source electrode 18c and a drain electrode 18d, which are provided in order on the base coat film 11 as illustrated in FIG. 3. Here, the semiconductor layer 12b is provided in an island shape on the base coat film 11 as illustrated in FIG. 3, and has, for example, a channel region, a source region, and a drain region. In addition, the gate insulating film 13 is provided to cover the semiconductor layer 12b as illustrated in FIG. 3. In addition, the gate electrode 14b is provided on the gate insulating film 13 to overlap the channel region of the semiconductor layer 12b as illustrated in FIG. 3. In addition, the first interlayer insulating film 15 and the second interlayer insulating film 17 is provided to cover the gate electrode 14b in order as illustrated in FIG. 3. In addition, the source electrode 18c and the drain electrode 18d are provided separated from each other on the second interlayer insulating film 17 as illustrated in FIG. 3. In addition, the source electrode 18c and the drain electrode 18d are electrically connected to the source region and the drain region of the semiconductor layer 12b, respectively, via contact holes formed in the layered film of the gate insulating film 13, the first interlayer insulating film 15, and the second interlayer insulating film 17 as illustrated in FIG. 3.

Further, although the top-gate type first TFT 9a and second TFT 9b are exemplified in the present embodiment, the first TFT 9a and the second TFT 9b may be bottom-gate type TFTs.

The capacitor 9c is electrically connected to the corresponding first TFT 9a and power source line 18g in each of the subpixels P as illustrated in FIG. 4. Here, as illustrated in FIG. 3, the capacitor 9c includes a lower conductive layer 14c formed of the same material as and in the same layer as the gate electrodes 14a and 14b, the first interlayer insulating film 15 provided to cover the lower conductive layer 14c, and an upper conductive layer 16 provided on the first interlayer insulating film 15 to overlap with the lower conductive layer 14c. Further, the upper conductive layer 16 is electrically connected to the power source line 18g via a contact hole formed in the second interlayer insulating film 17 as illustrated in FIG. 3.

The flattening film 19 has a flat surface in the display region D, and is made of, for example, an organic resin material such as a polyimide resin or an acrylic resin, or a polysiloxane-based spin on glass (SOG) material.

As illustrated in FIG. 3, the organic EL element layer 30 includes a plurality of organic EL elements 25, provided in an array of a matrix shape, which correspond to the plurality of subpixels, and an edge cover 22 provided in a lattice shape in common to all of the subpixels P to cover peripheral edge portions of first electrodes 21, which will be described later, of the organic EL elements 25.

As illustrated in FIG. 3, the organic EL element 25 includes, in each of the subpixels P, the first electrode 21 provided on the flattening film 19, an organic EL layer 23 provided on the first electrode 21, and a second electrode 24 provided on the organic EL layer 23.

As illustrated in FIG. 3, the first electrode 21 is electrically connected to the drain electrode 18d of the second TFT 9b of each of the subpixels P via a contact hole formed in the flattening film 19. In addition, the first electrode 21 has a function of injecting holes (positive holes) into the organic EL layer 23. In addition, the first electrode 21 is preferably formed of a material having a high work function to improve the efficiency in injection of holes into the organic EL layer 23. Here, examples of a material constituting the first electrode 21 include metal materials such as silver (Ag), aluminum (Al), vanadium (V), cobalt (Co), nickel (Ni), tungsten (W), gold (Au), titanium (Ti), ruthenium (Ru), manganese (Mn), indium (In), ytterbium (Yb), lithium fluoride (LiF), platinum (Pt), palladium (Pd), molybdenum (Mo), iridium (Ir), and tin (Sn). In addition, examples of the material constituting the first electrode 21 may include alloys such as astatine (At)/astatine oxide (AtO₂). Furthermore, the material constituting the first electrode 21 may be an electrically conductive oxide such as tin oxide (SnO), zinc oxide (ZnO), indium tin oxide (ITO), or indium zinc oxide (IZO). In addition, the first electrode 21 may be formed by layering a plurality of layers formed of any of the materials described above. Further, examples of compound materials having a high work function include indium tin oxide (ITO) and indium zinc oxide (IZO).

As illustrated in FIG. 5, the organic EL layer 23 includes a hole injection layer 1, a hole transport layer 2, a light-emitting layer 3, an electron transport layer 4, and an electron injection layer 5 that are sequentially provided on the first electrode 21.

The hole injection layer 1 is also called an anode buffer layer, and has a function of reducing an energy level difference between the first electrode 21 and the organic EL layer 23 to thereby improve the efficiency in injection of holes into the organic EL layer 23 from the first electrode 21. Here, examples of materials constituting the hole injection layer 1 include triazole derivatives, oxadiazole derivatives, imidazole derivatives, polyarylalkane derivatives, pyrazoline derivatives, phenylenediamine derivatives, oxazole derivatives, styrylanthracene derivatives, fluorenone derivatives, hydrazone derivatives, and stilbene derivatives.

The hole transport layer 2 has a function of improving the efficiency in hole transport from the first electrode 21 to the organic EL layer 23. Here, examples of materials constituting the hole transport layer 2 include porphyrin derivatives, aromatic tertiary amine compounds, styrylamine derivatives, polyvinylcarbazole, poly-p-phenylenevinylene, polysilane, triazole derivatives, oxadiazole derivatives, imidazole derivatives, polyarylalkane derivatives, pyrazoline derivatives, pyrazolone derivatives, phenylenediamine derivatives, arylamine derivatives, amine-substituted chalcone derivatives, oxazole derivatives, styrylanthracene derivatives, fluorenone derivatives, hydrazone derivatives, stilbene derivatives, hydrogenated amorphous silicon, hydrogenated amorphous silicon carbide, zinc sulfide, and zinc selenide.

The light-emitting layer 3 is a region where holes and electrons are injected from the first electrode 21 and the second electrode 24, respectively, and the holes and the electrons recombine when a voltage is applied via the first electrode 21 and the second electrode 24. Moreover, examples of materials constituting the light-emitting layer 3 include metal oxinoid compounds (8-hydroxyquinoline metal complexes), naphthalene derivatives, anthracene derivatives, diphenylethylene derivatives, vinyl acetone derivatives, triphenylamine derivatives, butadiene derivatives, coumarin derivatives, benzoxazole derivatives, oxadiazole derivatives, oxazole derivatives, benzimidazole derivatives, thiadiazole derivatives, benzothiazole derivatives, styryl derivatives, styrylamine derivatives, bisstyrylbenzene derivatives, trisstyrylbenzene derivatives, perylene derivatives, perinone derivatives, aminopyrene derivatives, pyridine derivatives, rhodamine derivatives, aquidine derivatives, phenoxazone, quinacridone derivatives, rubrene, poly-p-phenylenevinylene, and polysilane.

The electron transport layer 4 has a function of causing electrons to efficiently migrate to the light-emitting layer 3. Here, examples of materials constituting the electron transport layer 4 include oxadiazole derivatives, triazole derivatives, benzoquinone derivatives, naphthoquinone derivatives, anthraquinone derivatives, tetracyanoanthraquinodimethane derivatives, diphenoquinone derivatives, fluorenone derivatives, silole derivatives, and metal oxinoid compounds, as organic compounds.

The electron injection layer 5 has a function of reducing an energy level difference between the second electrode 24 and the organic EL layer 23 to thereby improve the efficiency in electron injection into the organic EL layer 23 from the second electrode 24, and this function lowers the drive voltage of the organic EL element 25. Further, the electron injection layer 5 is also referred to as a cathode buffer layer. Here, examples of materials constituting the electron injection layer 5 include inorganic alkaline compounds, such as lithium fluoride (LiF), magnesium fluoride (MgF₂), calcium fluoride (CaF₂), strontium fluoride (SrF₂), and barium fluoride (BaF₂), aluminum oxide (Al₂O₃), and strontium oxide (SrO).

As illustrated in FIG. 3, the second electrode 24 is provided to cover the organic EL layer 23 of each of the subpixels P and the edge cover 22 common to all the subpixels P. In addition, the second electrode 24 has a function of injecting electrons into the organic EL layer 23. In addition, it is more preferable that the second electrode 24 be formed of a material having a low work function to improve the efficiency in electron injection into the organic EL layer 23. Here, examples of the material constituting the second electrode 24 include silver (Ag), aluminum (Al), vanadium (V), cobalt (Co), nickel (Ni), tungsten (W), gold (Au), calcium (Ca), titanium (Ti), yttrium (Y), sodium (Na), ruthenium (Ru), manganese (Mn), indium (In), magnesium (Mg), lithium (Li), ytterbium (Yb), and lithium fluoride (LiF). In addition, the second electrode 24 may also be formed of an alloy of, for example, magnesium (Mg)-copper (Cu), magnesium (Mg)-silver (Ag), sodium (Na)-potassium (K), astatine (At)-astatine oxide (AtO₂), lithium (Li)-aluminum (Al), lithium (Li)-calcium (Ca)-aluminum (Al), and lithium fluoride (LiF)-calcium (Ca)-aluminum (Al), and the like. In addition, the second electrode 24 may be formed of a conductive oxide, for example, tin oxide (SnO), zinc oxide (ZnO), indium tin oxide (ITO), indium zinc oxide (IZO), or the like. In addition, the second electrode 24 may be formed by layering a plurality of layers formed of any of the materials described above. Further, examples of materials having a low work function include magnesium (Mg), lithium (Li), lithium fluoride (LiF), magnesium (Mg)/copper (Cu), magnesium (Mg)/silver (Ag), sodium (Na)/potassium (K), lithium (Li)/aluminum (Al), lithium (Li)/calcium (Ca)/aluminum (Al), and lithium fluoride (LiF)/calcium (Ca)/aluminum (Al).

The edge cover 22 is made of, for example, an organic resin material such as a polyimide resin or an acrylic resin, or a polysiloxane-based SOG material.

As illustrated in FIG. 3, the sealing film 35 is provided to cover the second electrode 24, includes a first inorganic sealing film 31, an organic sealing film 32, and a second inorganic sealing film 33 sequentially layered on the second electrode 24, and has a function of protecting the organic EL layer 23 of the organic EL element layer 25 from moisture and oxygen. Here, the first inorganic sealing film 31 and the second inorganic sealing film 33 include, for example, an inorganic insulating film such as a silicon nitride film, a silicon oxide film, and a silicon oxynitride film. Additionally, the organic sealing film 32 is made of, for example, an organic resin material such as an acrylic resin, an epoxy resin, a silicone resin, a polyurea resin, a parylene resin, a polyimide resin, a polyamide resin or the like.

As illustrated in FIG. 1, an IC chip 61 is mounted on the FPC 60. In addition, as illustrated in FIG. 1, a covering material 65a is provided on the FPC 60 to cover the IC chip 61 and its peripheral portion.

As illustrated in FIG. 1, the covering material 65a includes a chip protection layer 62a provided on the FPC 60, and an electromagnetic shielding layer 63 provided integrally with the chip protection layer 62a to be layered on the chip protection layer 62a.

The chip protection layer 62a is formed of a thermosetting resin, for example, an epoxy resin, formed to be thicker than the IC chip 61 to physically protect the IC chip 61. In addition, as illustrated in FIG. 1, the chip protection layer 62a includes a cured portion 62ₐₐ formed of a thermosetting resin in a U shape to surround the IC chip 61 in a plan view and an uncured portion 62_{ab} formed of a thermosetting resin provided in a part other than the cured portion 62aa.

The electromagnetic shielding layer 63 is formed of, for example, a metal sheet such as an aluminum sheet, and is provided to electromagnetically protect the IC chip 61.

The above-described organic EL display device 70a, in each of the subpixels P, inputs a gate signal to the first TFT 9a via the gate line 14 to turn on the first TFT 9a, writes a voltage corresponding to a source signal to the gate electrode 14b and the capacitor 9c of the second TFT 9b via the source line 18f, and supplies the organic EL layer 23 with a current from the power source line 18g defined based on the gate voltage of the second TFT 9b, whereby the light-emitting layer 3 of the organic EL layer 23 emits light to display an image. Further, in the organic EL display device 70a, even when the first TFT 9a is turned off, the gate voltage of the second TFT 9b is held by the capacitor 9c. Thus, the light emission by the light-emitting layer 3 is maintained until the gate signal of the next frame is input.

Next, a method for manufacturing the organic EL display device 70a according to the present embodiment will be described. Further, the method for manufacturing an organic EL display device 70a according to the present embodiment includes an organic EL display panel preparing step including a TFT layer forming step, an organic EL element layer forming step, and a sealing film forming step, a mounting step, an attachment step, and a curing step.

### Organic EL Display Panel Preparing Step

### TFT Layer Forming Step

For example, using a known method, the TFT layer 20 is formed by forming the base coat film 11, the first TFT 9a, the second TFT 9b, the capacitor 9c, and the second flattening film 19 on the resin substrate 10, which is formed on a glass substrate.

### Organic EL Element Layer Forming Step

The organic EL element layer 30 is formed by forming, using a known method, the first electrode 21, the edge cover 22, the organic EL layer 23 (the hole injection layer 1, the hole transport layer 2, the light-emitting layer 3, the electron transport layer 4, the electron injection layer 5), and the second electrode 24 on the flattening film 19 of the TFT layer 20 formed in the TFT layer forming step described above.

### Sealing Film Forming Step

First, an inorganic insulating film such as a silicon nitride film, a silicon oxide film, or a silicon oxynitride film is formed by a plasma CVD method on a substrate surface formed with the organic EL element layer 30 formed in the organic EL element layer forming process by using a mask to form the first inorganic sealing film 31.

Next, on the substrate surface formed with the first inorganic sealing film 31, a film made of an organic resin material such as acrylic resin is formed by, for example, using an ink-jet method to form the organic sealing film 32.

Thereafter, an inorganic insulating film, for example, a silicon nitride film, a silicon oxide film, or a silicon oxynitride film is formed by using the plasma CVD method on the substrate surface formed with the organic sealing film 32 by using a mask to form the second inorganic sealing film 33, thereby forming the sealing film 35.

Finally, after a protective sheet (not illustrated) is attached to the substrate surface on which the sealing film 35 has been formed, the glass substrate side of the resin substrate 10 is irradiated with laser light, thereby peeling the glass substrate off from the bottom face of the resin substrate 10, and a protective sheet (not illustrated) is attached to the bottom face of the resin substrate 10 from which the glass substrate has been peeled off.

The organic EL display panel 50 can be prepared as described above.

### Mounting Step

After an ACF is disposed at the terminal portion T of the organic EL display panel 50 prepared in the organic EL display panel preparing step, the FPC 60 on which the IC chip 61 is mounted is pressure-bonded via the ACF to mount the FPC 60.

### Attachment Step

As illustrated in FIG. 6, a covering material 65 formed by layering the chip protection layer 62 and the electromagnetic shielding layer 63 is attached onto the FPC 60 mounted in the mounting step from the chip protection layer 62 side to cover the IC chip 61 and its peripheral portion. Here, the covering material 65 is formed by applying a thermosetting resin to the back surface of the radio wave shielding sheet (63), and includes the chip protection layer 62 made of the thermosetting resin that is thicker than the IC chip 61 and the electromagnetic shielding layer 63 made of the radio wave shielding sheet (63).

### Curing Step

As illustrated in FIG. 7, an aligned heating tool 100a is brought into contact with the surface of the covering material 65 attached in the attachment step, i.e., the surface of the electromagnetic shielding layer 63, and the chip protection layer 62 is partially heated and cured to surround the IC chip 61 in a plan view, thereby forming the cured portion 62aa and the uncured portion 62ab in the chip protection layer 62, and forming the chip protection layer 62a and the covering material 65a including the chip protection layer (see FIG. 1). Here, the heating tool 100a has a built-in heater, and as illustrated in FIG. 7, a portion in contact with the surface of the electromagnetic shielding layer 63 is formed in a U shape in a plan view, and is configured to heat the chip protection layer 62 on the back surface side of the electromagnetic shielding layer 63 in a U shape in a plan view via the electromagnetic shielding layer 63 in contact therewith.

Thus, the organic EL display device 70a of the present embodiment can be manufactured as described above.

As described above, according to the organic EL display device 70a and the method for manufacturing the same of the present embodiment, the chip protection layer 62a and the electromagnetic shielding layer 63 layered on the chip protection layer 62a to electromagnetically protect the IC chip 61 are integrally provided on the FPC 60 on which the IC chip 61 is mounted to cover the IC chip 61 and its peripheral portion. Here, the chip protection layer 62a is thicker than the IC chip 61, is formed of a curable resin, and includes the cured portion 62ₐₐ provided to surround the IC chip 61 in a plan view to physically protect the IC chip 61 and the uncured portion 62_{ab} provided in a part other than the cured portion 62ₐₐ. In addition, in order to form the partially cured chip protection layer 62a having the cured portion 62ₐₐ and the uncured portion 62_{ab}, the covering material 65 formed by layering the (uncured) chip protection layer 62 and the electromagnetic shielding layer 63 is attached onto the FPC 60 in rough alignment to cover the IC chip 61 and its peripheral portion in the attachment step, and the heating tool 100a aligned with the IC chip 61 is brought into contact with the electromagnetic shielding layer 63 to partially heat and cure the uncured chip protection layer 62 in the curing step. As a result, the cured portion 62ₐₐ (and the other uncured portion 62_{ab}) that physically protect the IC chip 61 is formed in a self-aligned manner, and the electromagnetic shielding layer 63 that electromagnetically protects the IC chip 61 is layered on the cured portion 62aa and the uncured portion 62ab, and thus the IC chip 61 on the FPC 60 can be physically and electromagnetically protected with ease.

In addition, according to the organic EL display device 70a and the method for manufacturing the same according to the present embodiment, since the cured portion 62aa is provided in a U shape in a plan view, the widths W (see FIG. 1) of the cured portion 62aa can be reduced.

### Second Embodiment

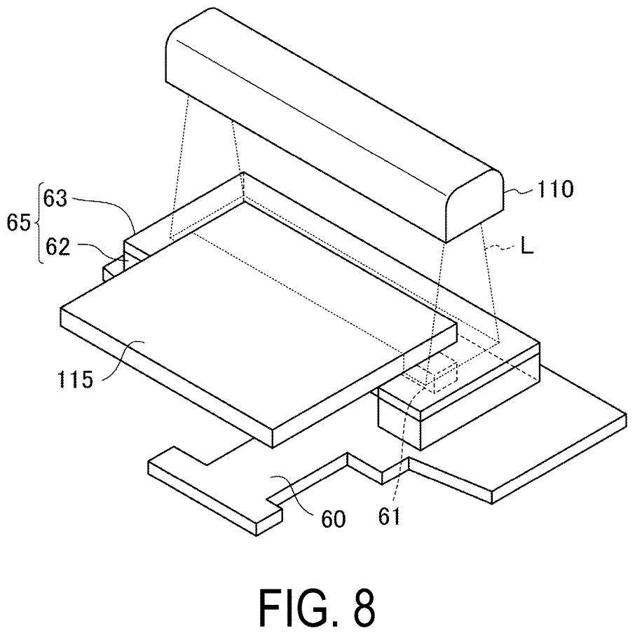

FIG. 8 illustrates a second embodiment of the display device and the method for manufacturing the same according to the disclosure. Here, FIG. 8 is a perspective view illustrating the curing step in the method for manufacturing the organic EL display device according to the present embodiment. Further, in the following embodiment, parts identical to those in FIG. 1 to FIG. 7 are designated by the same reference signs, and detailed descriptions thereof will be omitted.

Although the method for manufacturing the organic EL display device 70a using the heating tool 100a is exemplified in the above-described first embodiment, the present embodiment will describe a method for manufacturing an organic EL display device 70a using a heating irradiator 110.

The method for manufacturing the organic EL display device 70a according to the present embodiment includes an organic EL display panel preparing step including a TFT layer forming step, an organic EL element layer forming step, and a sealing film forming step, a mounting step, an attachment step, and a curing step as in the first embodiment. Further, since the organic EL display panel preparing step, the mounting step, and the attachment step in the present embodiment are substantially the same as the organic EL display panel preparing step, the mounting step, and the attachment step of the first embodiment, the curing step will be mainly described.

### Curing Step

As illustrated in FIG. 8, light L generated from the heating irradiator 110 is emitted to the surface of the covering material 65 attached in the attachment step of the first embodiment, i.e., the surface of the electromagnetic shielding layer 63, via a shielding plate 115, and the chip protection layer 62 is partially heated and cured to surround the IC chip 61 in a plan view, thereby forming the cured portion 62aa and the uncured portion 62ab in the chip protection layer 62, and forming the chip protection layer 62a and the covering material 65a including the chip protection layer (see FIG. 1). Here, the heating irradiator 110 is configured to emit light L such as infrared light in a rectangular shape in a plan view, for example, as illustrated in FIG. 8. Furthermore, the shielding plate 115 is provided in a rectangular shape in a plan view as illustrated in FIG. 8, and is formed of a metal plate such as a stainless steel plate.

Thus, the organic EL display device 70a of the present embodiment can be manufactured as described above.

As described above, according to the organic EL display device 70a and the method for manufacturing the same of the present embodiment, the chip protection layer 62a and the electromagnetic shielding layer 63 layered on the chip protection layer 62a to electromagnetically protect the IC chip 61 are integrally provided on the FPC 60 on which the IC chip 61 is mounted to cover the IC chip 61 and its peripheral portion. Here, the chip protection layer 62a is thicker than the IC chip 61, is formed of a curable resin, and includes the cured portion 62aa provided to surround the IC chip 61 in a plan view to physically protect the IC chip 61 and the uncured portion 62ab provided in a part other than the cured portion 62aa. In addition, in order to form the partially cured chip protection layer 62a having the cured portion 62aa and the uncured portion 62ab, the covering material 65 formed by layering the (uncured) chip protection layer 62 and the electromagnetic shielding layer 63 may be attached onto the FPC 60 in rough alignment to cover the IC chip 61 and its peripheral portion in the attachment step, and the light L emitted from the heating irradiator 110 aligned with the IC chip 61 may be radiated to the surface of the electromagnetic shielding layer 63 via the shielding plate 115 aligned with the IC chip 61, thereby partially heating and curing the uncured chip protection layer 62 in the curing step. As a result, the cured portion 62aa (and the other uncured portion 62ab) that physically protect the IC chip 61 is formed in a self-aligned manner, and the electromagnetic shielding layer 63 that electromagnetically protects the IC chip 61 is layered on the cured portion 62aa and the uncured portion 62ab, and thus the IC chip 61 on the FPC 60 can be physically and electromagnetically protected with ease.

In addition, according to the organic EL display device 70a and the method for manufacturing the same according to the present embodiment, since the cured portion 62aa is provided in a U shape in a plan view, the widths W of the cured portion 62aa can be reduced.

### Third Embodiment

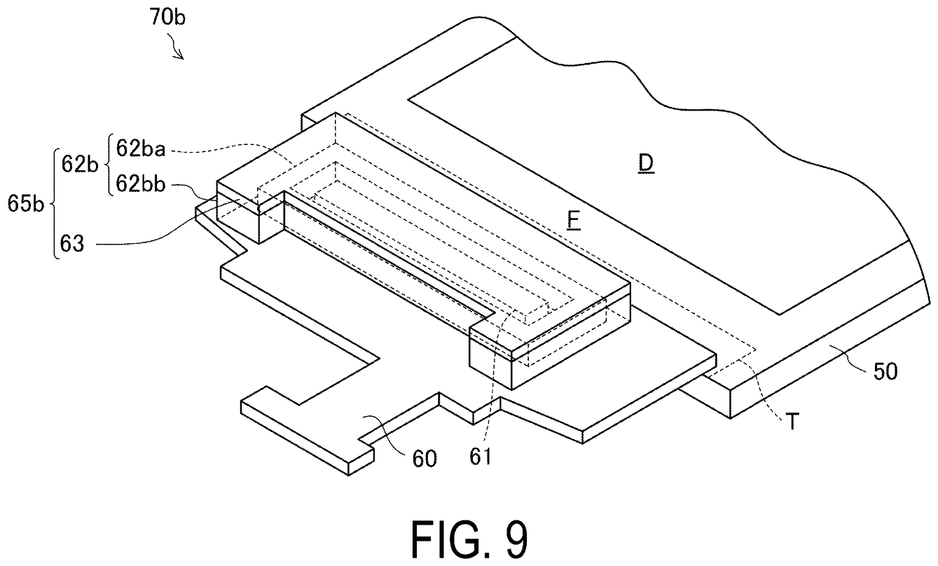

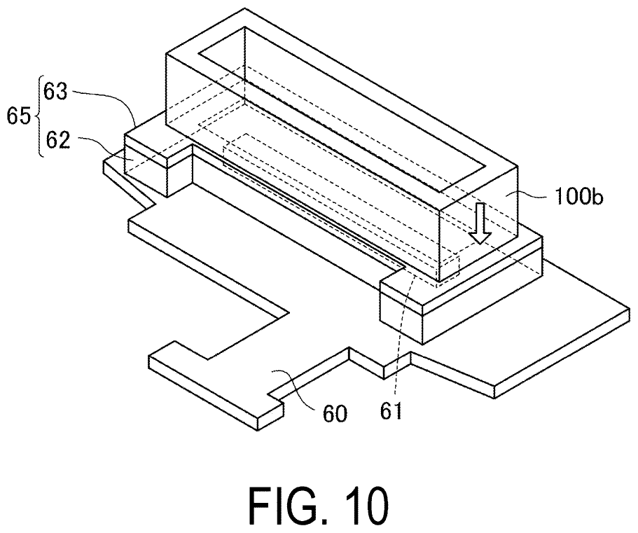

FIGS. 9 and 10 illustrate a third embodiment of a display device and a method for manufacturing the same according to the disclosure. Here, FIG. 9 is a perspective view of an organic EL display device 70b according to the present embodiment. In addition, FIG. 10 is a perspective view illustrating a curing step in the method for manufacturing the organic EL display device 70b.

Although the organic EL display device 70a in which the cured portion 62aa having a U shape in a plan view is provided and the method for manufacturing the same is exemplified in the first embodiment, in the present embodiment, the organic EL display device 70b in which a cured portion 62ba having an annular shape in a plan view is provided and a method for manufacturing the same is exemplified.

As illustrated in FIG. 9, the organic EL display device 70b includes, for example, an organic EL display panel 50 provided in a rectangular plate shape and a FPC 60 provided as a film substrate mounted on an edge portion of the organic EL display panel 50.

As illustrated in FIG. 9, an IC chip 61 is mounted on the FPC 60. In addition, as illustrated in FIG. 9, a covering material 65b is provided on the FPC 60 to cover the IC chip 61 and its peripheral portion.

As illustrated in FIG. 9, the covering material 65b includes a chip protection layer 62b provided on the FPC 60, and an electromagnetic shielding layer 63 provided integrally with the chip protection layer 62b to be layered on the chip protection layer 62b.

The chip protection layer 62b is formed of a thermosetting resin, for example, an epoxy resin, formed to be thicker than the IC chip 61 to physically protect the IC chip 61. In addition, as illustrated in FIG. 9, the chip protection layer 62b includes a cured portion 62ba formed of a thermosetting resin in a rectangular annular shape to surround the IC chip 61 in a plan view, and an uncured portion 62bb formed of a thermosetting resin provided in a part other than the cured portion 62ba.

Similar to the organic EL display device 70a of the first embodiment described above, the organic EL display device 70b described above has flexibility and is configured to display an image by causing a light-emitting layer 3 of an organic EL layer 23 to appropriately emit light via a first TFT 9a and a second TFT 9b in each subpixel P.

Next, a method for manufacturing the organic EL display device 70b according to the present embodiment will be described. Here, the method for manufacturing the organic EL display device 70b according to the present embodiment includes an organic EL display panel preparing step including a TFT layer forming step, an organic EL element layer forming step, and a sealing film forming step, a mounting step, an attachment step, and a curing step as in the first embodiment. Further, since the organic EL display panel preparing step, the mounting step, and the attachment step in the present embodiment are substantially the same as the organic EL display panel preparing step, the mounting step, and the attachment step of the first embodiment, the curing step will be mainly described.

### Curing Step

As illustrated in FIG. 10, an aligned heating tool 100b is brought into contact with the surface of the covering material 65 attached in the attachment step of the first embodiment, i.e., the surface of the electromagnetic shielding layer 63, and the chip protection layer 62 is partially heated and cured to surround the IC chip 61 in a plan view, thereby forming the cured portion 62ba and the uncured portion 62bb in the chip protection layer 62, and forming the chip protection layer 62b and the covering material 65b including the chip protection layer (see FIG. 9). Here, the heating tool 100b has a built-in heater, and as illustrated in FIG. 10, a portion in contact with the surface of the electromagnetic shielding layer 63 is formed in a rectangular annular shape in a plan view, and is configured to heat the chip protection layer 62 on the back surface side of the electromagnetic shielding layer 63 in a rectangular annular shape in a plan view via the electromagnetic shielding layer 63 in contact therewith.

The organic EL display device 70b of the present embodiment can be manufactured as described above.

As described above, according to the organic EL display device 70b and the method for manufacturing the same of the present embodiment, the chip protection layer 62b and the electromagnetic shielding layer 63 layered on the chip protection layer 62b to electromagnetically protect the IC chip 61 are integrally provided on the FPC 60 on which the IC chip 61 is mounted to cover the IC chip 61 and its peripheral portion. Here, the chip protection layer 62b is thicker than the IC chip 61, is formed of a curable resin, and includes the cured portion 62ba provided to surround the IC chip 61 in a plan view to physically protect the IC chip 61 and the uncured portion 62bb provided in a part other than the cured portion 62ba. In addition, in order to form the partially cured chip protection layer 62b having the cured portion 62ba and the uncured portion 62bb, the covering material 65 formed by layering the (uncured) chip protection layer 62 and the electromagnetic shielding layer 63 is attached onto the FPC 60 in rough alignment to cover the IC chip 61 and its peripheral portion in the attachment step, and the heating tool 100b aligned with the IC chip 61 is brought into contact with the electromagnetic shielding layer 63 to partially heat and cure the uncured chip protection layer 62 in the curing step. As a result, the cured portion 62ba (and the other uncured portion 62bb) that physically protect the IC chip 61 is formed in a self-aligned manner, and the electromagnetic shielding layer 63 that electromagnetically protects the IC chip 61 is layered on the cured portion 62ba and the uncured portion 62bb, and thus the IC chip 61 on the FPC 60 can be physically and electromagnetically protected with ease.

In addition, according to the organic EL display device 70b and the method for manufacturing the same of the present embodiment, since the cured portion 62ba is provided in a rectangular annular shape in a plan view and is provided to surround the IC chip 61 from the four sides, it is possible to physically and reliably protect the IC chip 61.

### Fourth Embodiment

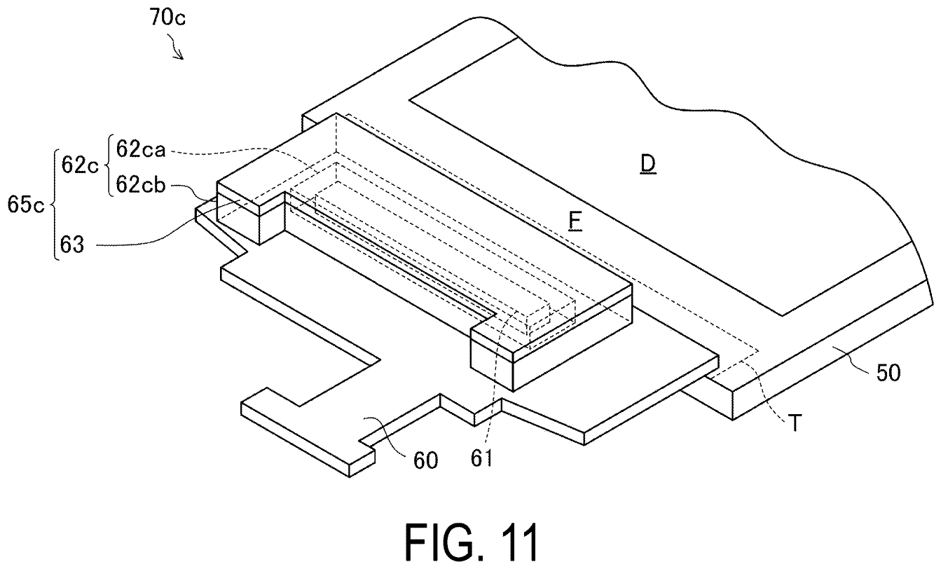

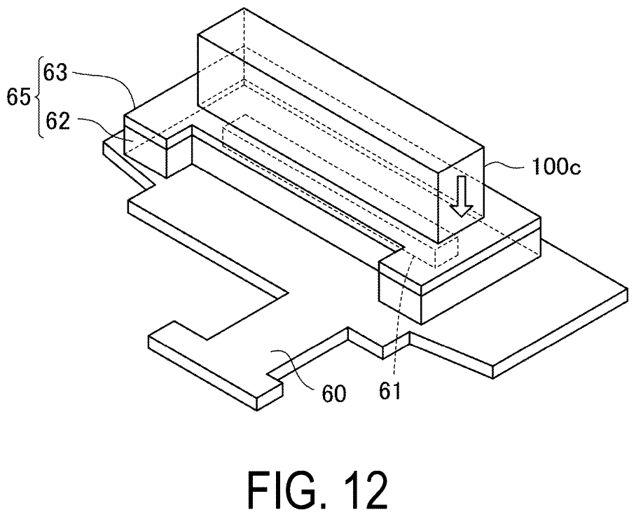

FIGS. 11 and 12 illustrate a fourth embodiment of the display device and the method for manufacturing the same according to the disclosure. Here, FIG. 11 is a perspective view of an organic EL display device 70c according to the present embodiment. In addition, FIG. 12 is a perspective view illustrating the curing step in the method for manufacturing the organic EL display device 70c.

Although the organic EL display device 70a (70b) in which the cured portion 62aa (62ba) is provided to cover the IC chip 61 in a plan view and the method for manufacturing the same are exemplified in the first (third) embodiment, in the present embodiment, an organic EL display device 70c in which a cured portion 62ca is provided to cover the IC chip 61 in a plan view and a method for manufacturing the same are exemplified.

As illustrated in FIG. 11, the organic EL display device 70c includes, for example, an organic EL display panel 50 provided in a rectangular plate shape and a FPC 60 provided as a film substrate mounted on an edge portion of the organic EL display panel 50.

As illustrated in FIG. 11, the IC chip 61 is mounted on the FPC 60. In addition, as illustrated in FIG. 11, a covering material 65c is provided on the FPC 60 to cover the IC chip 61 and its peripheral portion.

As illustrated in FIG. 11, the covering material 65c includes a chip protection layer 62c provided on the FPC 60, and an electromagnetic shielding layer 63 provided integrally with the chip protection layer 62c to be layered on the chip protection layer 62c.

The chip protection layer 62c is formed of a thermosetting resin, for example, an epoxy resin, formed to be thicker than the IC chip 61 to physically protect the IC chip 61. In addition, as illustrated in FIG. 11, the chip protection layer 62c includes a cured portion 62ca formed of a thermosetting resin in a rectangular shape to cover the IC chip 61 in a plan view, and an uncured portion 62cb formed of a thermosetting resin provided in a part other than the cured portion 62ca.

Similar to the organic EL display device 70a of the first embodiment described above, the organic EL display device 70c described above has flexibility and is configured to display an image by causing a light-emitting layer 3 of an organic EL layer 23 to appropriately emit light via a first TFT 9a and a second TFT 9b in each subpixel P.

Next, a method for manufacturing the organic EL display device 70c according to the present embodiment will be described. Here, the method for manufacturing the organic EL display device 70c according to the present embodiment includes an organic EL display panel preparing step including a TFT layer forming step, an organic EL element layer forming step, and a sealing film forming step, a mounting step, an attachment step, and a curing step as in the first embodiment. Further, since the organic EL display panel preparing step, the mounting step, and the attachment step in the present embodiment are substantially the same as the organic EL display panel preparing step, the mounting step, and the attachment step of the first embodiment, the curing step will be mainly described.

### Curing Step

As illustrated in FIG. 12, an aligned heating tool 100c is brought into contact with the surface of the covering material 65 attached in the attachment step of the first embodiment, i.e., the surface of the electromagnetic shielding layer 63, and the chip protection layer 62 is partially heated and cured to cover the IC chip 61 in a plan view, thereby forming the cured portion 62ca and the uncured portion 62cb in the chip protection layer 62, and forming the chip protection layer 62c and a covering material 65c including the chip protection layer (see FIG. 11). Here, the heating tool 100c has a built-in heater, and as illustrated in FIG. 12, a portion in contact with the surface of the electromagnetic shielding layer 63 is formed in a rectangular shape in a plan view, and is configured to heat the chip protection layer 62 on the back surface side of the electromagnetic shielding layer 63 in a rectangular shape in a plan view via the electromagnetic shielding layer 63 in contact therewith.

The organic EL display device 70c of the present embodiment can be manufactured as described above.

As described above, according to the organic EL display device 70c and the method for manufacturing the same of the present embodiment, the chip protection layer 62c and the electromagnetic shielding layer 63 layered on the chip protection layer 62c to electromagnetically protect the IC chip 61 are integrally provided on the FPC 60 on which the IC chip 61 is mounted to cover the IC chip 61 and its peripheral portion. Here, the chip protection layer 62c is thicker than the IC chip 61, is formed of a curable resin, and includes the cured portion 62ca provided to cover the IC chip 61 in a plan view to physically protect the IC chip 61 and the uncured portion 62cb provided in a part other than the cured portion 62ca. In addition, in order to form the partially cured chip protection layer 62c having the cured portion 62ca and the uncured portion 62cb, the covering material 65 formed by layering the (uncured) chip protection layer 62 and the electromagnetic shielding layer 63 is attached onto the FPC 60 in rough alignment to cover the IC chip 61 and its peripheral portion in the attachment step, and the heating tool 100c aligned with the IC chip 61 is brought into contact with the electromagnetic shielding layer 63 to partially heat and cure the uncured chip protection layer 62 in the curing step. As a result, the cured portion 62ca (and the other uncured portion 62cb) that physically protect the IC chip 61 is formed in a self-aligned manner, and the electromagnetic shielding layer 63 that electromagnetically protects the IC chip 61 is layered on the cured portion 62ca and the uncured portion 62cb, and thus the IC chip 61 on the FPC 60 can be physically and electromagnetically protected with ease.

In addition, according to the organic EL display device 70c and the method for manufacturing the same of the present embodiment, since the portion of the heating tool 100c in contact with the electromagnetic shielding layer 63 is formed in a rectangular shape in a plan view, the heating tool 100c has a simple shape, and thus the manufacturing cost of the organic EL display device 70c can be reduced and the accuracy in alignment of the heating tool 100c in the curing step can be relaxed.

### Fifth Embodiment

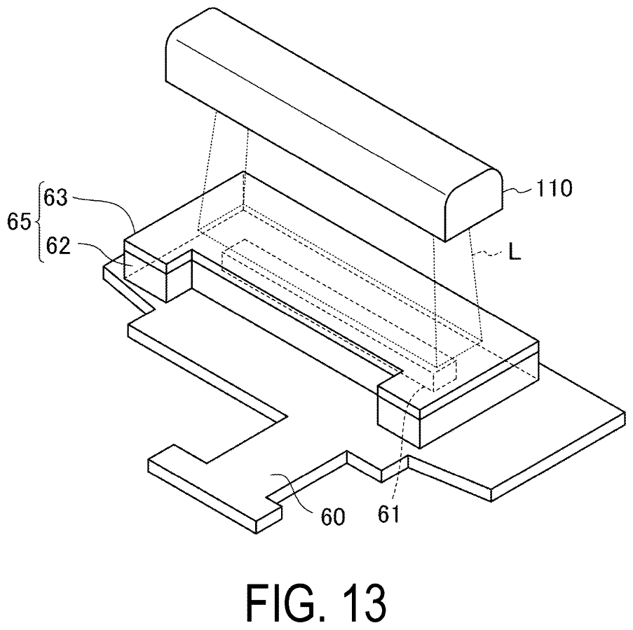

FIG. 13 illustrates a fifth embodiment of a display device and a method for manufacturing the same according to the disclosure. Here, FIG. 13 is a perspective view illustrating a curing step in the method for manufacturing an organic EL display device according to the present embodiment.

Although the method for manufacturing the organic EL display device 70c using the heating tool 100c is exemplified in the above-described fourth embodiment, the present embodiment will describe a method for manufacturing an organic EL display device 70c using a heating irradiator 110.

Here, the method for manufacturing the organic EL display device 70c according to the present embodiment includes an organic EL display panel preparing step including a TFT layer forming step, an organic EL element layer forming step, and a sealing film forming step, a mounting step, an attachment step, and a curing step as in the first embodiment. Further, since the organic EL display panel preparing step, the mounting step, and the attachment step in the present embodiment are substantially the same as the organic EL display panel preparing step, the mounting step, and the attachment step of the first embodiment, the curing step will be mainly described.

### Curing Step

As illustrated in FIG. 13, light L generated from the heating irradiator 110 is emitted to the surface of the covering material 65 attached in the attachment step of the first embodiment, i.e., the surface of the electromagnetic shielding layer 63, and the chip protection layer 62 is partially heated and cured to cover the IC chip 61 in a plan view, thereby forming the cured portion 62ca and the uncured portion 62cb in the chip protection layer 62, and forming the chip protection layer 62c and the covering material 65c including the chip protection layer (see FIG. 11).

The organic EL display device 70c of the present embodiment can be manufactured as described above.

As described above, according to the organic EL display device 70c and the method for manufacturing the same of the present embodiment, the chip protection layer 62c and the electromagnetic shielding layer 63 layered on the chip protection layer 62c to electromagnetically protect the IC chip 61 are integrally provided on the FPC 60 on which the IC chip 61 is mounted to cover the IC chip 61 and its peripheral portion. Here, the chip protection layer 62c is thicker than the IC chip 61, is formed of a curable resin, and includes the cured portion 62ca provided to cover the IC chip 61 in a plan view to physically protect the IC chip 61 and the uncured portion 62cb provided in a part other than the cured portion 62ca. In addition, in order to form the partially cured chip protection layer 62c having the cured portion 62ca and the uncured portion 62cb, the covering material 65 formed by layering the (uncured) chip protection layer 62 and the electromagnetic shielding layer 63 is attached onto the FPC 60 in rough alignment to cover the IC chip 61 and its peripheral portion in the attachment step, and light L emitted from the heating irradiator 110 aligned with the IC chip 61 is radiated to a surface of the electromagnetic shielding layer 63 to partially heat and cure the uncured chip protection layer 62 in the curing step. As a result, the cured portion 62ca (and the other uncured portion 62cb) that physically protect the IC chip 61 is formed in a self-aligned manner, and the electromagnetic shielding layer 63 that electromagnetically protects the IC chip 61 is layered on the cured portion 62ca and the uncured portion 62cb, and thus the IC chip 61 on the FPC 60 can be physically and electromagnetically protected with ease.

Furthermore, according to the organic EL display device 70c and the method for manufacturing the same of the present embodiment, since the cured portion 62ca and the uncured portion 62cb are formed by directly irradiating the surface of the electromagnetic shielding layer 63 with the light L emitted from the heating irradiator 110, the manufacturing cost of the organic EL display device 70c can be reduced.

### Other Embodiments

Although the organic EL display device in which the chip protection layer is formed of a thermosetting resin and the method for manufacturing the same are exemplified in each of the embodiments, for example, by using a transparent conductive sheet for the electromagnetic shielding layer, the chip protection layer may be formed of a photocurable resin such as an ultraviolet (UV) curable resin.

Although the organic EL layer having a five-layer structure including the hole injection layer, the hole transport layer, the light-emitting layer, the electron transport layer, and the electron injection layer has been exemplified in each of the embodiments described above, the organic EL layer may have a three-layer structure including a hole injection-cum-transport layer, a light-emitting layer, and an electron transport-cum-injection layer, for example.

In each of the embodiments described above, the organic EL display device including the first electrode as an anode electrode and the second electrode as a cathode electrode is exemplified. The disclosure is also applicable to an organic EL display device in which the layered structure of the organic EL layer is reversed with the first electrode being a cathode electrode and the second electrode being an anode electrode.

Although the organic EL display device in which the electrode of the TFT connected to the first electrode serves as the drain electrode has been exemplified in each of the embodiments described above, the disclosure is also applicable to an organic EL display device in which the electrode of the TFT connected to the first electrode is referred to as the source electrode.

In each of the embodiments described above, the organic EL display device is exemplified as a display device. The disclosure can also be applied to a display device including a plurality of light-emitting elements driven by a current, for example, to a display device including quantum dot light-emitting diodes (QLEDs), which are a light-emitting element using a quantum dot-containing layer.

### INDUSTRIAL APPLICABILITY

As described above, the disclosure is useful for a flexible display device.

1. A display device comprising:
a display panel; and
a film substrate which is mounted at an edge portion of the display panel and on which an integrated circuit chip is mounted,
the display device including, on the film substrate, a chip protection layer and an electromagnetic shielding layer layered on the chip protection layer integrally provided to cover the integrated circuit chip and a peripheral portion of the integrated circuit chip,
wherein a thickness of the chip protection layer is greater than a thickness of the integrated circuit chip, and
the chip protection layer is formed of a curable resin, and includes a cured portion of the curable resin provided to surround the integrated circuit chip or cover the integrated circuit chip in a plan view, and an uncured portion of the curable resin provided in a part other than the cured portion.

2. The display device according to claim 1,
wherein the cured portion is provided in a U shape in a plan view.

3. The display device according to claim 1,
wherein the cured portion is provided in an annular shape in a plan view.

4. The display device according to claim 1,
wherein the cured portion is provided in a rectangular shape in a plan view.

5. The display device according to claim 1,
wherein the electromagnetic shielding layer is formed of a metal sheet, and
the curable resin is a thermosetting resin.

6. The display device according to claim 1,
wherein the display panel is an organic electroluminescence display panel.

7. A method for manufacturing a display device comprising:
mounting a film substrate on which an integrated circuit chip is mounted at an edge portion of a display panel;
attaching, on the film substrate, a covering material formed by layering a chip protection layer and an electromagnetic shielding layer from a chip protection layer side to cover the integrated circuit chip and a peripheral portion of the integrated circuit chip, the chip protection layer being formed by applying a curable resin on a back surface of a radio wave shielding sheet and formed of the curable resin thicker than the integrated circuit chip, and the electromagnetic shielding layer being formed of the radio wave shielding sheet; and
partially curing the chip protection layer,
wherein, in the curing, a cured portion is formed by curing the chip protection layer to surround the integrated circuit chip or to cover the integrated circuit chip in a plan view and an uncured portion is formed in a part other than the cured portion.

8. The method for manufacturing a display device according to claim 7,
wherein the radio wave shielding sheet is a metal sheet, and
the curable resin is a thermosetting resin.

9. The method for manufacturing a display device according to claim 8,
wherein, in the curing, the chip protection layer is cured by bringing a heating tool into contact with a surface of the electromagnetic shielding layer to heat the chip protection layer.

10. The method for manufacturing a display device according to claim 9,
wherein a portion of the heating tool in contact with the surface of the electromagnetic shielding layer is provided in a U shape in a plan view.

11. The method for manufacturing a display device according to claim 9,
wherein a portion of the heating tool in contact with the surface of the electromagnetic shielding layer is provided in an annular shape in a plan view.

12. The method for manufacturing a display device according to claim 9,
wherein a portion of the heating tool in contact with the surface of the electromagnetic shielding layer is provided in a rectangular shape in a plan view.

13. The method for manufacturing a display device according to claim 8,
wherein, in the curing, the chip protection layer is cured by a heating irradiator irradiating a surface of the electromagnetic shielding layer with light to heat the chip protection layer.

14. The method for manufacturing a display device according to claim 13,
wherein the heating irradiator is configured to emit light in a rectangular shape in a plan view.

15. The method for manufacturing a display device according to claim 14,
wherein, in the curing, the surface of the electromagnetic shielding layer is irradiated with light via a shielding plate having a rectangular shape in a plan view.

16. The method for manufacturing a display device according to claim 7,
wherein the display panel is an organic electroluminescence display panel.
